(19) United States
(12) Patent Application Publication
(10) Pub. No.: US 2014/0233194 A1
(43) Pub. Date: Aug. 21, 2014

(54) COVER WINDOW AND DISPLAY DEVICE WITH COVER WINDOW

(71) Applicant: Samsung Display Co., Ltd., Yongin-City (KR)

(72) Inventors: Yuki HONGO, Yongin-City (KR); Kwan-Young HAN, Yongin-City (KR); Ju-Suk OH, Yongin-City (KR)

(21) Appl. No.: 14/169,595

(22) Filed: Jan. 31, 2014

(30) Foreign Application Priority Data
Feb. 18, 2013 (KR) 10-2013-0017051

(51) Int. Cl. H05K 1/02

(52) U.S. Cl. CPC H05K 1/0283
USPC 361/749; 428/174

(57) ABSTRACT

In a display device, a cover window is capable of increasing transparency of a curved part to improve visibility of a screen and appearance quality of a product. The cover window for the display device includes at least one curved part. In addition, the curved part includes an outer surface formed in an arc having a curvature radius of r1 and an inner surface formed in an arc having a curvature radius of r2, where r1≦r2≦2r1.

### CLAIM OF PRIORITY

This application makes reference to, incorporates into this specification the entire contents of, and claims all benefits accruing under 35 U.S.C. §119 from an application earlier filed in the Korean Intellectual Property Office on Feb. 18, 2013 and there duly assigned Serial No. 10-2013-0017051.

### BACKGROUND OF THE INVENTION

1. Field of the Invention

The present invention relates to a cover window, and more particularly, to a cover window having a curved part and a display device with the cover window.

2. Description of the Related Art

A display device includes a display panel displaying an image and a transparent cover window covering a display surface of the display panel. The cover window protects the display panel from external impact and scratches that occur in use, and the like. Generally, the cover window is made of a plastic resin and is manufactured by an injection molding method using a mold.

Recently, as the use of a smart phone and a tablet PC has increased, diversity in design of a display device installed in these devices has been required. In order to meet diverse standards of design, a flexible display panel and a display device with the cover window with a curved part have been proposed.

However, when a resin material flows along the curved part in the process of manufacturing the cover window with the curved part by the injection molding method, a temperature difference partially occurs, and thus a convection phenomenon occurs, such that fluidity deteriorates. In this case, abnormal elements hindering transparency occur in the curved part of the completed cover window, such that visibility of a screen and an appearance quality of a product deteriorate.

The above information disclosed in this Background section is only for enhancement of an understanding of the background of the invention, and therefore it may contain information that does not form the prior art that is already known in this country to a person of ordinary skill in the art.

### SUMMARY OF THE INVENTION

The present invention has been developed in an effort to provide a cover window capable of increasing transparency of a curved part to improve visibility of a screen and appearance quality of a product in the cover window with the curved part, and a display device with the cover window.

An exemplary embodiment of the present invention provides a cover window for a display device including at least one curved part. The curved part includes an outer surface formed in an arc having a curvature radius of r1 and an inner surface formed in an arc having a curvature radius of r2, and meets a condition of r1≦r2≦2r1.

The cover window may be made of a plastic material having a thermal distortion temperature of 90° C. to 150° C. The cover window may include any one selected from a group consisting of polycarbonate, cyclo olefin polymer, and polymethylmethacrylate. The cover window may have a thickness of 0.4 mm to 1.0 mm.

The cover window may include a flat part and the curved parts may be disposed at both sides of the flat part. The pair of curved parts disposed at both sides of the flat part may be formed to have the same curvature and may be disposed at a side having the same curvature center.

On the other hand, the curved parts may be continuously formed along one direction of the cover window, and two adjacent curved parts of the plurality of curved parts may have the curvature centers disposed at sides facing each other.

Another exemplary embodiment of the present invention provides a display device including: a flexible display panel; and a cover window disposed at an outer side of a display surface of the display panel and including at least one curved part. The curved part includes an outer surface formed in an arc having a curvature radius of r1 and an inner surface formed in an arc having a curvature radius of r2, and meets a condition of r1≦r2≦2r1.

The cover window may be made of a plastic material having a thermal distortion temperature of 90° C. to 150° C. The cover window may include any one selected from a group consisting of polycarbonate, cyclo olefin polymer, and polymethylmethacrylate. The cover window may have a thickness of 0.4 mm to 1.0 mm.

The cover window may include a flat part and the curved parts may be disposed at both sides of the flat part. The pair of curved parts disposed at both sides of the flat part may be formed to have the same curvature and may be disposed at a side having the same curvature center. On the other hand, the curved parts may be continuously formed along one direction of the cover window, and two adjacent curved parts of the plurality of curved parts may have the curvature centers disposed at sides facing each other.

A touch sensor unit and a polarizing film may be positioned between the display panel and the cover window

The display panel may be an organic light emitting display panel including a plurality of organic light emitting diodes.

When the curved part is filled with the resin material in the process of manufacturing the cover window by the injection molding method, the convection phenomenon due to the temperature difference can be reduced, thereby securing high fluidity. Therefore, the cover window can suppress the occurrence of abnormal elements hindering the transparency of the curved part, thereby improving the visibility and appearance quality.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is a perspective view of a cover window according to a first exemplary embodiment of the present invention.

FIG. 2 is an enlarged view of a curved part in the cover window illustrated in FIG. 1.

FIG. 3 is a schematically enlarged view of a part of a mold for manufacturing the cover window illustrated in FIG. 2.

FIG. 4 is an enlarged view illustrating a curved part in a cover window of a Comparative Example.

FIG. 5 is a perspective view of a cover window according to a second exemplary embodiment of the present invention.

FIG. 6 is a perspective view of a cover window according to a third exemplary embodiment of the present invention.

FIG. 7 is a perspective view of a cover window according to a fourth exemplary embodiment of the present invention.

FIG. 8 is a partial cross-sectional view of a display device according to a fifth exemplary embodiment of the present invention.

FIG. 9 is a partially enlarged cross-sectional view of an organic light emitting display panel.

### DETAILED DESCRIPTION OF THE INVENTION

In the following detailed description, only certain exemplary embodiments of the present invention have been shown and described, simply by way of illustration. As those skilled in the art will realize, the described embodiments may be modified in various different ways, all without departing from the spirit or scope of the present invention.

In the specification, unless explicitly described to the contrary, the word “comprise” and variations such as “comprises” or “comprising” will be understood to imply the inclusion of stated elements but not the exclusion of any other elements. Furthermore, in the specification, it will be understood that, when an element such as a layer, film, region, or substrate is referred to as being “on” another element, it can be directly on the other element or intervening elements may also be present. Furthermore, in the specification, the word “on” means positioning on or below the object portion, but does not essentially mean positioning on the upper side of the object portion based on a gravity direction.

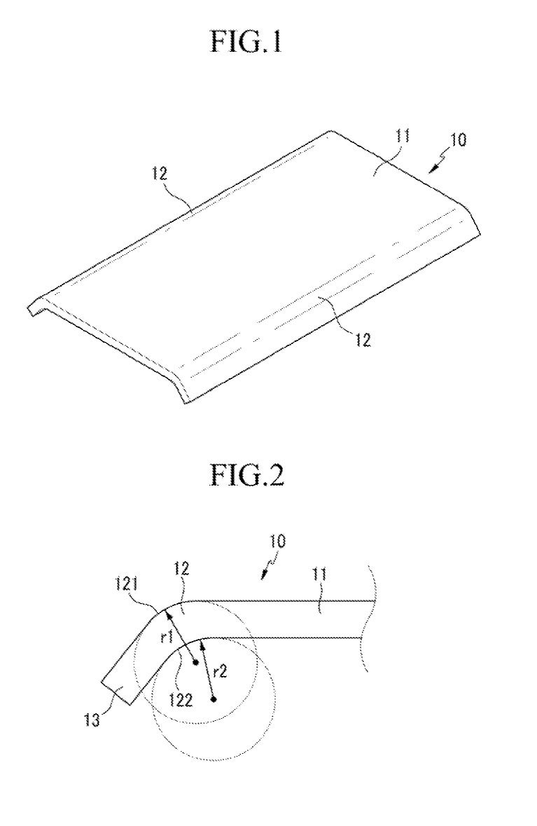

FIG. 1 is a perspective view of a cover window according to a first exemplary embodiment of the present invention and FIG. 2 is an enlarged view of a curved part in the cover window illustrated in FIG. 1.

Referring to FIGS. 1 and 2, a cover window 10 according to the first exemplary embodiment of the present invention includes a flat part 11 and a pair of curved parts 12 that are disposed at both sides of the flat part 11.

The cover window 10 is made of a transparent plastic resin and is manufactured by an injection molding method using a mold. In this case, the flat part 11 and the pair of curved parts 12 are integrally formed without a boundary therebetween to configure the cover window 10.

The pair of curved parts 12 may be formed at both sides of the flat part 11 in parallel with a long side of the cover window 10. In addition, the pair of curved parts 12 may be formed to have a predetermined shape along a direction in parallel with the long side of the cover window 12 without a change in curvature.

The pair of curved parts 12 may be formed to have the same curvature and the curvature centers of the two curved parts 12 may be disposed at the same side.

FIG. 1 illustrates, by way of example, a case in which the curvature centers of the two curved parts 12 are disposed under the cover window 10. The cover window 10 may further include a flat part 13 having a predetermined width (see FIG. 2) that contacts outer edges of each curved part 12.

The curved part 12 includes an outer surface 121 formed in an arc having a curvature radius of r1 and an inner surface 122 formed in an arc having a curvature radius of r2. In this case, a surface of a side at which the curvature centers of the two surfaces 121 and 122 of the curved part 12 are disposed is defined as an ‘inner surface’ and the other surface is defined as an ‘outer surface’.

The curved part 12 in the cover window 10 according to the exemplary embodiment of the present invention satisfies the following condition 1.

r1≦r2≦2r1 1

That is, r2 is set to be a size one or two times larger than r1. When r2 is equal to r1, an arc length of the inner surface 122 of the curved part is equal to that of the outer surface 121 of the curved part. When r2 is larger than r1, an arc length of the inner surface 122 of the curved part is longer than that of the outer surface 121 of the curved part. However, the arc length of the inner surface 122 of the curved part is limited to a condition in which r2 is within two times as large as r1.

FIG. 2 illustrates, by way of example, the case in which r1 is equal to r2. The curved part 12 having the shape characteristic according to the condition 1 may have a partially varying thickness. For example, the thickness measured at the center of the curved part 12 may be larger than the thickness measured at the edge of the curved part 12 that contacts the flat part 11.

When r2 exceeds two times r1, the difference in thickness for each position of the curved part 12 is increased, and thus the visibility may deteriorate. Furthermore, since the arc length of the inner surface 122 of the curved part is excessively large as compared to the arc length of the outer surface 121 of the curved part, it is difficult to reduce the difference in temperature of the resin material during the injection molding process to be described below.

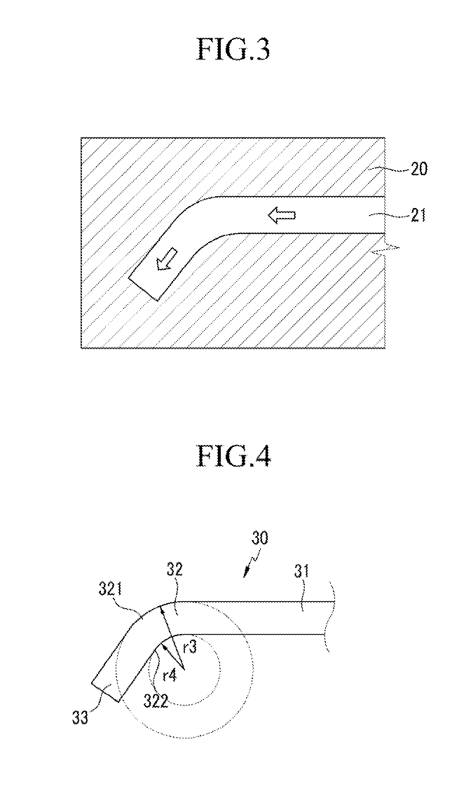

FIG. 3 is a schematically enlarged view of a part of a mold for manufacturing the cover window illustrated in FIG. 2.

Referring to FIGS. 2 and 3, a mold 20 has an inner space 21 having the same shape as the cover window 10 and forms an injection port (not illustrated) into which the heated resin material is injected. The injection port may be prepared at a position corresponding to a center of the cover window 10.

The resin material sprayed from the injection port is spread toward the edge of the inner space 21. That is, the resin material fills the entire space corresponding to the flat part 11, flows along the curved part 12, and fills the curved part 12. In this case, the outside portion of the resin material flowing in the inner space 21 of the mold 20 results in loss of heat much more than the central portion thereof due to the contact with the mold 20.

Since the curved part 12 is a place at which the flow direction of the resin material is changed, factors hindering the flow of the resin material need to be reduced as much as possible to prevent the fluidity from being reduced. In the cover window 10 according to the exemplary embodiment of the present invention, the arc length of the inner surface 122 of the curved part is equal to or larger than the outer surface 121 of the curved part within a range meeting the foregoing condition 1.

Therefore, the length (the arc length of the outer surface 121 of the curved part) contacting the mold 20 at the outer surface 121 of the curved part is equal to or has little difference from the length (the arc length of the inner surface 122 of the curved part) contacting the mold at the inner surface 122 of the curved part, such that when the resin material filling the flat part 11 flows along the curved part 12, the difference in temperature of the outside portion of the resin material contacting the mold 20 may be minimized.

Therefore, when the curved part 12 is filled with the resin material, the convection phenomenon due to the temperature difference is reduced, and thus high fluidity may be secured. As a result, the cover window 10 according to the exemplary embodiment of the present invention suppresses the occurrence of abnormal elements hindering the transparency of the curved part 12, thereby improving the visibility and the appearance quality.

FIG. 4 is an enlarged view illustrating a curved part in a cover window of a Comparative Example.

Referring to FIG. 4, a curved part 32 in a cover window 30 of the Comparative Example includes an outer surface 321 formed in an arc having a curvature radius of r3 and an inner surface 322 formed in an arc having a curvature radius of r4 and meets a condition of r3>r4. Therefore, the arc length of the outer surface 321 of the curved part is longer than that of the inner surface 322 of the curved part.

When a resin material filling a flat part 31 flows along the curved part 32 in the cover window 30 of the Comparative Example, an outside portion of the resin material contacting the outer surface 321 of the curved part is cooled more quickly than other portions of the resin materials due to a length difference between the outer surface 321 and the inner surface 322 of the curved part.

Therefore, the convection phenomenon occurs within the curved part 32 while a lower portion of the resin material having a relatively higher temperature floats, such that the fluidity of the resin material deteriorates, thereby generating the abnormal elements hindering the transparency of the curved part 32.

However, the cover window 10 according to the exemplary embodiment of the present invention reduces the convection phenomenon due to the temperature difference when the resin material fills the curved part 12, due to the shape characteristics of the curved part 12 meeting the foregoing condition 1, to secure the high fluidity, thereby increasing the transparency of the curved part 12.

Referring back to FIGS. 1 and 2, the cover window 10 according to the exemplary embodiment of the present invention is made of a plastic material, the thermal distortion temperature of which is 90° C. to 150° C., and may include, for example, any one of polycarbonate (PC), cyclo olefin polymer (COP), and polymethylmethacrylate (PMMA). In this case, the PMMA does not include a rubber component.

When the thermal distortion temperature of the plastic material configuring the cover window 10 is less than 90° C., reliability of the cover window 10 may deteriorate, and when the thermal distortion temperature thereof exceeds 150° C., the cover window 10 is injection-molded and then a residual stress is liable to remain, such that a curl may occur in the cover window 10.

The cover window 10 according to the exemplary embodiment of the present invention may be formed to have a thickness of 0.4 mm to 1.0 mm. When the thickness of the cover window 10 is less than 0.4 mm, rigidity of the cover window 10 itself is reduced, such that impact resistance may be reduced, and when the thickness thereof exceeds 1.0 mm, the thickness of the cover window 10 becomes excessively large, such that a display device may be difficult to be thinned.

FIG. 5 is a perspective view of a cover window according to a second exemplary embodiment of the present invention.

Referring to FIG. 5, a cover window 101 according to the second exemplary embodiment of the present invention has the same configuration as the cover window 10 according to the first exemplary embodiment of the present invention, except that a pair of curved parts 12 is formed to be in parallel with a short side of the cover window 101 at both sides of the flat part 11. The same members as the first exemplar embodiment of the present invention are denoted by same reference numerals, and therefore components different from the first exemplary embodiment of the present invention will be mainly described below.

The pair of curved parts 12 may be formed to have a predetermined shape along a direction in parallel with the short side of the cover window 101 without changing the curvature. The pair of curved parts 12 is formed to have the same curvature, and a center of the curvatures of the two curved parts 12 may be disposed at the same side. The cover window 101 may further include a flat part having a predetermined width that contacts the outer edges of each curved part 12. The pair of curved parts 12 meets the foregoing shape condition 1.

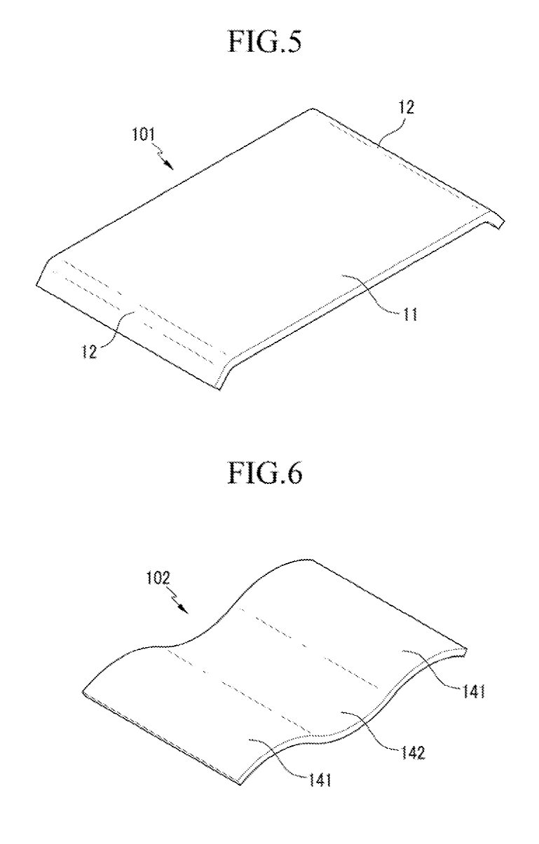

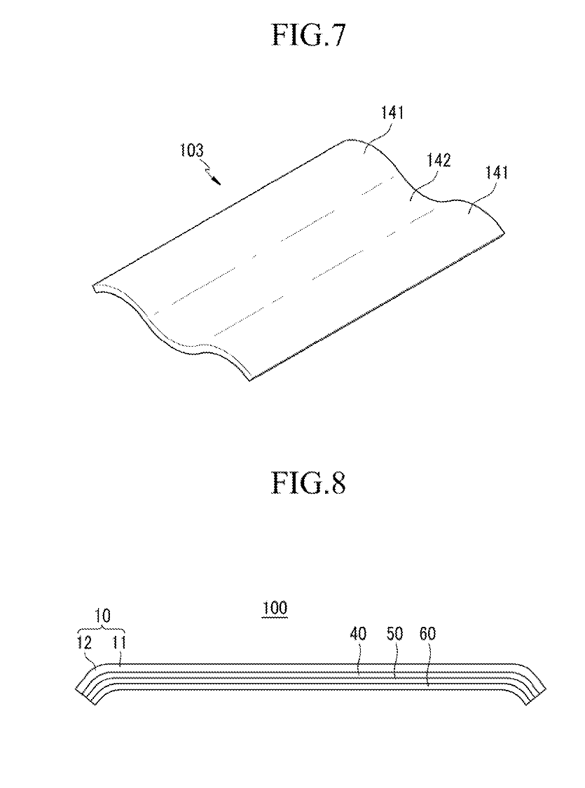

FIG. 6 is a perspective view of a cover window according to a third exemplary embodiment of the present invention and FIG. 7 is a perspective view of a cover window according to a fourth exemplary embodiment of the present invention.

Referring to FIG. 6, a cover window 102 according to the third exemplary embodiment of the present invention is configured of a plurality of curved parts 141 and 142 that are connected along a direction in parallel with a long side of the cover window 102 without a flat part. Referring to FIG. 7, a cover window 103 according to the fourth exemplary embodiment of the present invention is configured from the plurality of curved parts 141 and 142 that is connected along a direction in parallel with a short side of the cover window 103 without a flat part.

In the third exemplary embodiment and the fourth exemplary embodiment according to the present invention, the two adjacent curved parts 141 and 142 have the curvature centers disposed at sides facing each other. Therefore, the cover windows 102 and 103 are formed to have a shape in which the protruded curved part 141 and the depressed curved part 142 are alternately connected one by one.

The plurality of curved parts 141 and 142 is formed to have the same curvature or at least one curved part 141 or 142 may be formed to have a curvature different from the other curved part 141 or 142. FIGS. 6 and 7 illustrate, by way of example, the case in which the plurality of curved parts 141 and 142 is formed to have the same curvature.

Each curved part 141 or 142 meets the foregoing condition 1 and reduces the convection phenomenon due to the difference in temperature of the resin material during the injection molding, thereby securing the high fluidity. In addition, the cover windows 102 and 103 may be made of a plastic material, the thermal distortion temperature of which is 90° C. to 150° C., and may be formed to have a thickness of 0.4 mm to 1.0 mm.

The experimental results of the cover windows according to Examples 1, 2, and 3 that meet the foregoing condition 1 and the cover windows of Comparative Examples 1 and 2 that do not meet the condition 1 are shown in the following Table 1.

TABLE 1

| | | Thermal | | | | |
|---|---|---|---|---|---|---|
| | | distortion | | | Appear- | Heat |
| | | temperature | r1 | r2 | ance | resis- |
| | Material | (° C.) | (mm) | (mm) | quality | tance |
| Example 1 | PC | 123 | 20 | 20 | Good | Good |
| Example 2 | PC | 123 | 20 | 30 | Good | Good |
| Example 3 | COP | 99 | 20 | 20 | Good | Good |
| Comparative | PC | 123 | 20 | 5 | Poor | Good |
| Example 1 | | | | | | |
| Comparative | PMMA | 74 | 20 | 5 | Good | Poor |
| Example 2 | | | | | | |

In the above Table, PC represents polycarbonate, COP represents cyclo olefin polymer, and PMMA represents polymethylmethacrylate. In the case of Examples 1, 2, and 3 meeting the foregoing condition 1, it is shown that both the appearance quality and the heat resistance are good, and in the case of Comparative Examples 1 and 2 that do not meet the condition 1, it may be confirmed that any one of the appearance quality and the heat resistance is poor.

In this case, the appearance quality was evaluated based on whether transmitted light is distorted when the cover window is disposed on the display panel and light emitted from the display panel is observed through the curved part of the cover window. That is, when the distortion of the transmitted light is observed, the appearance quality is determined to be poor, and when the distortion of the transmitted light is not observed, the cover window is determined to be good. In addition, after the cover window is put in the environment of a temperature of 85° C. and a humidity of 85% for 24 hours, if the change in the size of a product after and before the cover window is put is within 2%, the heat resistance is determined to be good, and if the change in a size of a product exceeds 2%, the heat resistance is determined to be poor.

FIG. 8 is a partial cross-sectional view of a display device according to a fifth exemplary embodiment of the present invention.

Referring to FIG. 8, a display device 100 according to the fifth exemplary embodiment of the present invention includes a cover window 10, a touch sensor unit 40, a polarizing film 50, and a display panel 60.

The cover window 10 is a cover window including at least one curved part 12 meeting the foregoing condition 1, and is the cover window according to any one of the first to fourth exemplary embodiments of the present invention as described above. FIG. 8 illustrates, by way of example, the cover window 10 according to the first exemplary embodiment of the present invention.

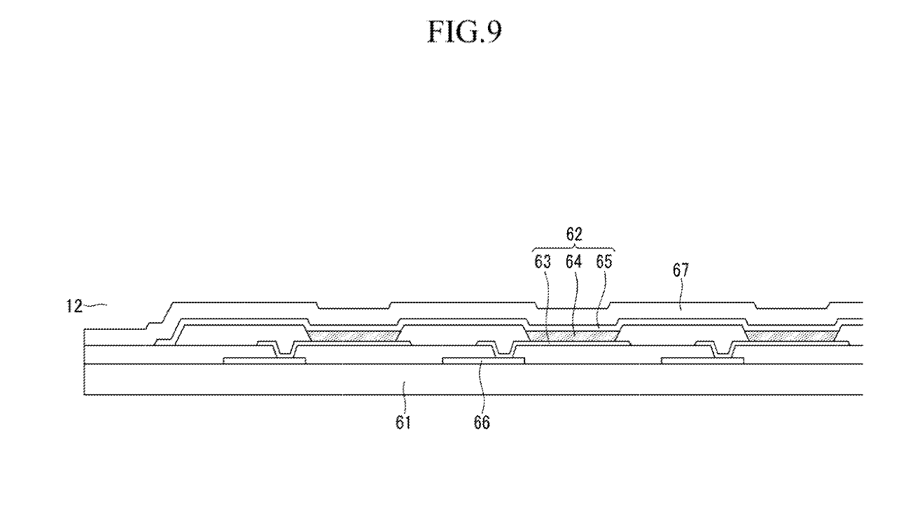

The display panel 60 is a flexible display panel. The display panel 60 has a configuration in which a plurality of pixels is disposed on a polymer film and may be an organic light emitting display panel including a plurality of organic light emitting diodes or a liquid crystal display panel including a liquid crystal layer and a color filter layer. FIG. 9 illustrates an organic light emitting display panel, by way of example.

FIG. 9 is a partially enlarged cross-sectional view of an organic light emitting display panel. Referring to FIG. 9, the organic light emitting display panel includes a substrate 61, a plurality of pixel circuits and a plurality of organic light emitting diodes 62 formed on the substrate 61, a thin film encapsulation layer 67 covering the plurality of organic light emitting diodes 62. The substrate 61 is formed of a flexible polymer film.

A pixel circuit and an organic light emitting diode 62 are disposed in each pixel, one by one. The pixel circuit includes at least two thin film transistors (switching thin film transistor and driving thin film transistor) and at least one capacitor. The organic light emitting diode 62 includes a pixel electrode 63, an organic light emitting layer 64, and a common electrode 65.

The switching thin film transistor is used as a switching element for selecting a pixel to be light emitted, and the driving thin film transistor serves to apply driving power for light emitting from the organic light emitting layer 64 of the selected pixel to the pixel electrode 63.

FIG. 9 schematically illustrates only a driving thin film transistor 66 as one layer in the pixel circuit. The pixel electrodes 63 are each provided for each pixel and are electrically connected with the driving thin film transistor 66. On the other hand, the common electrodes 65 are formed over the substrate 61, without being differentiated for each pixel.

Any one of the pixel electrode 63 and the common electrode 65 is an anode that is a hole injection electrode and the other thereof is a cathode that is an electron injection electrode. The hole injected from the anode and the electrode injected from the cathode are combined in the organic light emitting layer 64 to generate exciton and light is emitted while the exciton emit energy.

In this case, any one of the pixel electrode 63 and the common electrode 65 may be formed of a metal layer and the other thereof may be formed of a transflective layer or a transparent conductive layer. Light from the organic light emitting layer 64 is reflected from a metal layer, transmits the transflective layer or the transparent conductive layer, and is then emitted to the outside.

The thin film encapsulation layer 67 encapsulates the plurality of organic light emitting diodes 62 to suppress deterioration in the organic light emitting diodes 62 due to external moisture and oxygen. The thin film encapsulation layer 67 may have a structure in which at least one organic layer and at least one inorganic layer are alternately stacked one by one. In addition, the uppermost layer exposed to the outside in the thin film encapsulation layer 67 may be formed of the inorganic layer to prevent vapor permeability into the organic light emitting diode 62.

The organic layer of the thin film encapsulation layer 67 is made of polymer, for example, may be a single layer or a multilayer that is made of any one of polyethyleneterephthalate, polyimide, polycarbonate, epoxy, polyethylene, and polyacrylate. The inorganic layer of the thin film encapsulation layer 67 may be a single or a multilayer that includes metal oxide or metal nitride. For example, the inorganic layer may include any one of SiNx, Al₂O₃, SiO₂, and TiO₂.

Referring back to FIG. 8, the display panel 60 is disposed so that a display surface to which light is emitted faces the cover window 10 and has a curved shape corresponding to the cover window 10.

The touch sensor unit 40 and the polarizing film 50 may be disposed between the cover window 10 and the display panel 60. The touch sensor unit 40 is attached to the cover window 10 by a transparent adhesive layer (not illustrated) and the display panel 60 to which the polarizing film 50 is attached is attached to the touch sensor unit 40 by the transparent adhesive layer (not illustrated). The polarizing film 50 serves to suppress the external light reflection to improve the visibility.

The display device 100 includes the cover windows 10, 101, 102, and 103 according to any one of the first to fourth exemplary embodiments of the present invention so as to increase the transparency of the curved part 12 of the cover window, thereby improving the visibility of a screen and the appearance quality of a product.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A cover window for a display device including at least one curved part, wherein said at least one curved part includes an outer surface formed in an arc having a curvature radius of r1 and an inner surface formed in an arc having a curvature radius of r2, and wherein a condition of r1≦r2≦2r1 is met.

2. The cover window for a display device of claim 1, wherein the cover window is made of a plastic material having a thermal distortion temperature in a range of 90° C. to 150° C.

3. The cover window for a display device of claim 2, wherein the cover window includes any one selected from a group consisting of polycarbonate, cyclo olefin polymer, and polymethylmethacrylate.

4. The cover window for a display device of claim 1, wherein the cover window has a thickness in a range of 0.4 mm to 1.0 mm.

5. The cover window for a display device of claim 1, wherein the cover window includes a flat part, and said at least one curved part comprises a pair of curved parts, each curved part being disposed at a respective side of the flat part.

6. The cover window for a display device of claim 5, wherein the curved parts disposed at respective sides of the flat part are formed to have a same curvature and are disposed at a side having a same curvature center.

7. The cover window for a display device of claim 1, wherein said at least one curved part comprises a plurality of curved parts which are continuously formed along one direction of the cover window, and two adjacent curved parts of the plurality of curved parts have curvature centers disposed at sides facing each other.

8. A display device, comprising:
a flexible display panel; and
a cover window disposed at an outer side of a display surface of the display panel and including at least one curved part;
wherein said at least one curved part includes an outer surface formed in an arc having a curvature radius of r1 and an inner surface formed in an arc having a curvature radius of r2; and
wherein a condition of r1≦r2≦2r1 is met.

9. The display device of claim 8, wherein the cover window is made of a plastic material having a thermal distortion temperature in a range of 90° C. to 150° C.

10. The display device of claim 9, wherein the cover window includes any one selected from a group consisting of polycarbonate, cyclo olefin polymer, and polymethylmethacrylate.

11. The display device of claim 8, wherein the cover window has a thickness in a range of 0.4 mm to 1.0 mm.

12. The display device of claim 8, wherein the cover window includes a flat part, and said at least one curved part comprises a pair of curved parts, each curved part being disposed at a respective side of the flat part.

13. The display device of claim 12, wherein the curved parts disposed at respective sides of the flat part are formed to have a same curvature and are disposed at a side having a same curvature center.

14. The display device of claim 8, wherein said at least one curved part comprises a plurality of curved parts which are continuously formed along one direction of the cover window, and two adjacent curved parts of the plurality of curved parts have curvature centers disposed at sides facing each other.

15. The display device of claim 8, further comprising a touch sensor unit and a polarizing film positioned between the display panel and the cover window.

16. The display device of claim 8, wherein the display panel is an organic light emitting display panel including a plurality of organic light emitting diodes.
